(19) United States
(12) Patent Application Publication
(10) Pub. No.: US 2006/0139046 A1
(43) Pub. Date: Jun. 29, 2006

(54) Apparatus for reducing deflection of a mobile member in a chamber

(75) Inventors: Larry J. Lape, Lake Jackson, TX (US); Hasan Giray Kaya, (US)

Correspondence Address: E. RANDALL SMITH, 2777 ALLEN PARKWAY, SUITE 800, HOUSTON, TX, 77019, US

(73) Assignee: Reliability Inc.

(21) Appl. No.: 11/104,269

(22) Filed: Apr. 12, 2005

Related U.S. Application Data
(60) Provisional application No. 60/561,602, filed on Apr. 13, 2004.

(51) Int. Cl. F27D 11/00; G01R 31/02

(52) U.S. Cl. 324/760; 219/385

(57) ABSTRACT

In one embodiment, an apparatus for reducing deflection of a mobile member in a chamber includes at least one receiver projecting from a base member in the chamber and at least one engager projecting from the mobile member. Each engager is matable with a receiver when the mobile member is inserted into the chamber. When at least one retractable mechanism disposed in the chamber engages the mobile member or at least one device carried thereon, each engager engages a receiver, reducing deflection of the mobile member.

This application claims the benefit of U.S. Provisional Pat. App. Ser. No. 60/561,602 filed Apr. 13, 2004 and entitled Apparatus and Methods for Reducing Deflection of a Member in a Chamber, having attorney docket number 1055.0700 and at least one common inventor, Hasan Giray Kaya, as the present application.

### BACKGROUND OF THE INVENTION

The invention relates to apparatus, systems and methods for reducing deflection of a mobile member in a chamber.

Various operations involve the temporary application of force(s) to a mobile member in a chamber, such as for testing or stressing the member or devices carried on the member. Under the applied force(s), the member may undesirably bow, bend or deflect. The present invention reduces such bowing, bending or deflection with the use of a temporary mechanical attachment of the member to another structure in the chamber.

The mobile member, chamber and related components may have any form, configuration and construction. Some systems, for example, involve the insertion of one or more board-like member into an environmentally controllable chamber for testing or stressing the member or devices carried on the member. For illustrative purposes, one type of mobile member is a burn-in board used for carrying integrated circuit packages (“IC packages”) to be tested or stressed in a testing or burn-in chamber. An example of a burn-in system is described in U.S. Pat. No. 6,166,555 to Lillja et al. and dated Dec. 26, 2000, which is hereby incorporated by reference herein in its entirety.

In some burn-in systems, the IC packages are loaded onto one side of each burn-in board and the boards are slid into the testing chamber in a card cage or on rails. The burn-in boards are reused many times on a rapid basis, making their effectiveness, durability and ease of use critical for efficient and reliable operations. Typically, a testing assembly, such as a thermal solution adapter (TSA), is located in the chamber for engaging the IC packages and applying heat (or other influence). The TSA often includes a fixed structure from which retractable mechanisms, such “heat sinks”, move into and out of connection with the IC packages. The connection of the heat sink with the IC package should be precise for accurate and effective stressing or testing, such as to transmit heat to the IC package. Accordingly, positioning and alignment of the mobile member and the TSA are critical.

The retractable mechanisms typically apply force to the burn-in board when engaging the IC packages, which can cause the board to deflect, bend or bow. In this particular application (which the present invention is not limited to), as the size of IC packages and the carrying capacity of the burn-in boards increases over time to meet greater technology capability and cost saving demands, the forces placed upon the boards will increase, increasing the likelihood of undesirable deflection, even with the use of reinforced testing boards and chambers.

Deflection, bending or bowing of the mobile member may be undesirable for various reasons. For example, it may lead to contact failure between the retractable mechanism and the device being tested or engaged, resulting in test failures or inaccuracies. For another example, the testing board may become warped, bent or damaged and consequently difficult or impossible to effectively or reliably use further. For yet another example, the rails or cage within which the boards are loaded may become deformed or damaged. There are yet other potential consequences resulting from deflection or bowing of mobile members. It should be understood, however, that each embodiment of the present invention and each claim of this patent does not necessarily address or solve every, or any particular, such disadvantage or consequence.

Thus, there remains a need for apparatus, systems and methods for reducing the undesirable deflection of a mobile member is a chamber having one or more of the following attributes, capabilities or features: reduces deflection of the mobile member with at the least one set of temporary interconnecting mechanical connectors or members; reduces deflection of a mobile member with the use of at least one temporary mechanical attachment of the member to a fixed structure in the chamber; provides a temporary mechanical linkage between the mobile member and another member that allows opposing forces to counterbalance each other locally, generally preventing the forces to be applied to a long moment arm, thus reducing deflection; counterbalances compression forces on the mobile member; reduces horizontal loading on the card cage or rails that hold the mobile member in the chamber; utilizes at least one engager projecting from the mobile member and at least one receiver projecting from a base member in the chamber to provide temporary mechanical connection thereof; minimizes tension or loading on connectors used to secure the engagers to the mobile member; includes engagers and receivers positioned to allow unimpeded mating of the intended mating pairs of engagers and receivers; focuses the non-deflection effort in the area on the mobile member most susceptible to deflection; enables the mobile members to be inserted, removed and reinserted repeatedly without substantial bending to the mobile members; assists in maintaining a coplanar relationship between the mobile member and the front and rear plates of a thermal solution adapter in a burn-in or other environmentally controllable chamber; occupies minimal space; is easy to manufacture and install; is easy to disassemble and reassemble; is easy to inspect and service, adjust and/or repair; is easily applied to existing systems by retrofitting; increases the longevity and usefulness of the mobile members; increases the reliability and effectiveness of the mobile members; eliminates the need for heavy and bulky stiffeners on the mobile member to reduce deflection of the mobile members; eliminates the need for a stout cage (for holding the mobile members in the chamber) to reduce deflection of the mobile members; or any combination thereof. It should be clearly understood that the present invention does not require all, or any one or particular group, of the above attributes, capabilities or features.

### BRIEF SUMMARY OF THE INVENTION

Various embodiments of the present invention involve an apparatus for reducing deflection of a mobile member in a chamber. The chamber includes at least one base member and at least one retractable mechanism. The deflection of the mobile member may be caused by engagement of the retractable mechanism with the mobile member or at least one device carried thereon. In accordance with the invention, at least three receivers project from a first side of the base member and at least three engagers project from a first side of the mobile member. The first sides of the base and mobile members face each other. Each engager is matable with one of the receivers when the mobile member is inserted into the chamber. When the retractable mechanism engages the mobile member or at least one device carried thereon, each engager engages one of the receivers, reducing deflection of the mobile member. Each engager is disengageable from a receiver when the retractable mechanism is disengaged from the mobile member or device(s) carried thereon and the mobile member is removed from the chamber.

Certain embodiments of the present invention involve an apparatus for reducing deflection of a carrying board in a chamber. The carrying board includes at least two vertical stiffeners and is insertable into and removable from the chamber. The chamber includes at least one thermal solution adapter having a fixed plate mounted within the chamber and plurality of heat silks. The heat sinks are movable relative to the fixed plate and into engagement with the carrying board or at least one device disposed upon the carrying board. The deflection of the carrying board is caused by engagement of at least one heat sink with the carrying board or at least one device carried thereon. In accordance with the present invention, at least one receiver projects from a first side of the fixed plate proximate to the center of the height of the fixed plate. At least one engager projects from a first side of the carrying board proximate to the center of the height of the carrying board. The first sides of the fixed plate and the carrying board face each other. Each engager is interconnected with at least one of the vertical stiffeners, and matable with a receiver when the carrying board is inserted into the chamber. When the heat sink engages the carrying board or device(s) carried thereon, each engager engages a receiver, reducing deflection of the carrying board. Each engager is disengageable from the receiver after the heat sink is disengaged from the carrying board or device(s) carried thereon and the carrying board is removed from the chamber.

Accordingly, the present invention includes features and advantages which are believed to enable it to advance technology associated with the application of force to a mobile member in a chamber. Characteristics and advantages of the present invention described above and additional features and benefits will be readily apparent to those skilled in the art upon consideration of the following detailed description of preferred embodiments and referring to the accompanying drawings.

### BRIEF DESCRIPTION OF THE DRAWINGS

For a detailed description of preferred embodiments of the invention, reference will now be made to the accompanying drawings wherein:

FIG. 1 is a partial side view of an embodiment of a deflection reduction assembly in accordance with the present invention showing a mated exemplary engager and receiver;

FIG. 2 is a partial perspective view of the exemplary mobile member shown in the embodiment of FIG. 1;

FIG. 3 is a partial perspective view of the exemplary base member shown in the embodiment of FIG. 1;

FIG. 4 is a partial top view of another embodiment of a deflection reduction assembly in accordance with the present invention showing multiple exemplary pairs of mated engages and receivers;

FIG. 5A is a plan view of the example mobile member shown in FIG. 4;

FIG. 5B is a bottom view of the example mobile member of FIG. 5A;

FIG. 6 is a rear view of the example base member shown in FIG. 4;

FIG. 7 is an isolated top view of the exemplary engager shown in FIG. 4;

FIG. 8A is an isolated side view of the exemplary engager mount shown in FIG. 5A;

FIG. 8B is a top view of the exemplary engager mount of FIG. 8A;

FIG. 9A is an isolated top view of the exemplary receiver shown in FIG. 4; and

FIG. 9B is a side view of the exemplary receiver of FIG. 9A.

### DETAILED DESCRIPTION OF PREFERRED EMBODIMENTS OF THE INVENTION

Preferred embodiments of the invention are shown in the above-identified figures and described in detail below. It should be understood that the appended drawings and description herein are of preferred embodiments and are not intended to limit the invention or the appended claims. On the contrary, the intention is to cover all modifications, equivalents and alternatives falling within the spirit and scope of the invention as defined by the appended claims. In showing and describing preferred embodiments, like or identical reference numerals are used to identify common or similar elements. The figures are not necessarily to scale and certain features and certain views of the figures may be shown exaggerated in scale or in schematic in the interest of clarity and conciseness.

As used herein and throughout all the various portions (and headings) of this patent, the terms “invention”, “present invention” and variations thereof mean one or more embodiment and are not intended to mean the claimed invention of any particular appended claim(s) or all of the appended claims. Accordingly, the subject or topic of each such reference is not automatically or necessarily part of, or required by, any particular claim(s) merely because of such reference. It should also be noted that references herein to a particular item or component in the singular or plural tense means “one or more” such component.

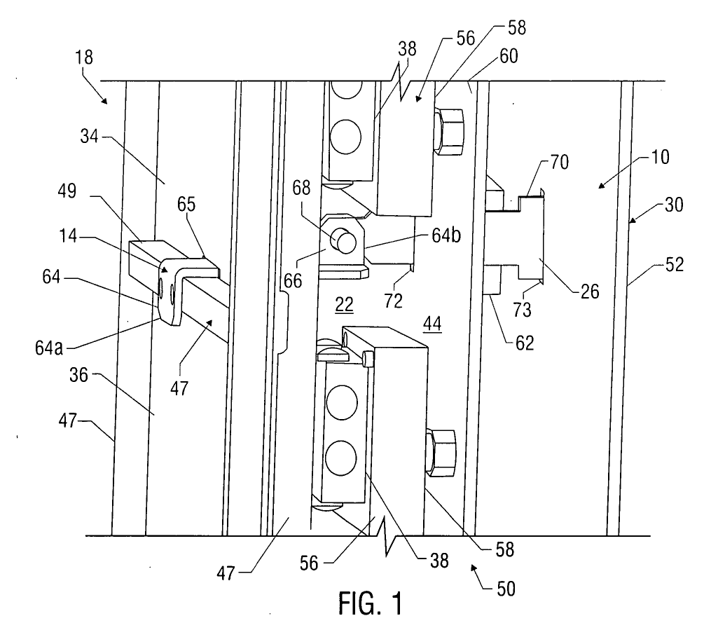

Referring initially to FIG. 1, an embodiment of a deflection reduction assembly (DRA) 10 in accordance with the present invention is shown. The DRA 10 includes at least one engager 14 projecting from a mobile member 18 and at least one receiver 26 projecting from a base member 30. The mobile member 18 is insertable into a testing, or environmentally controllable, chamber 22 and the base member 30 is fixed within the chamber 22. The DRA 10 is designed so that when the mobile member 18 is loaded into the chamber 22, each engager 14 mates with a receiver 26, respectively. During testing or other activity occurring within the chamber 22, the corresponding engagers 14 and receivers 26 are capable of engaging one another, reducing deflection, bending or bowing of the mobile member 18.

In the particular example of FIGS. 1 and 2, the mobile member 18 is a carrying board 34 used for carrying devices (not shown) to be tested, stressed or otherwise affected in the chamber 22. If desired, the carrying board 34 may include a framework of stiffeners 47, such as to assist in preserving the shape and integrity of the board 34 during use. The illustrated carrying board 34 is designed to be inserted in an upright position or vertical orientation into the chamber 22, such as into a cage or onto rails (not shown). However, the present invention is not limited to an upright or vertically inserted mobile member 18 and other similarly aligned components as described with respect to the embodiments below and shown in the appended drawings. For example, there may be embodiments having the mobile member 18 inserted and/or other components arranged in a horizontal, slanted or other orientation or any desired configuration.

An example of a carrying board 34 is a flat printed circuit board, or burn-in board, 36 having multiple sockets 38 on its front face 37 for carrying numerous integrated circuits (not shown) to be stressed or tested in a burn-in chamber 44, as is and further becomes known in the art. However, the present invention is not limited to use with burn-in boards and burn-in chambers. The “mobile member” 18 or “carrying board” 34 may be any portable or mobile plate or board-like member, or any other shaped or configured member that is insertable into and removable from a chamber wherein it may be subject to forces that could cause it to deflect or bend. The “chamber” 22 may be any enclosure or space within which a mobile member or carrying board may be inserted and subject to deflection or bending.

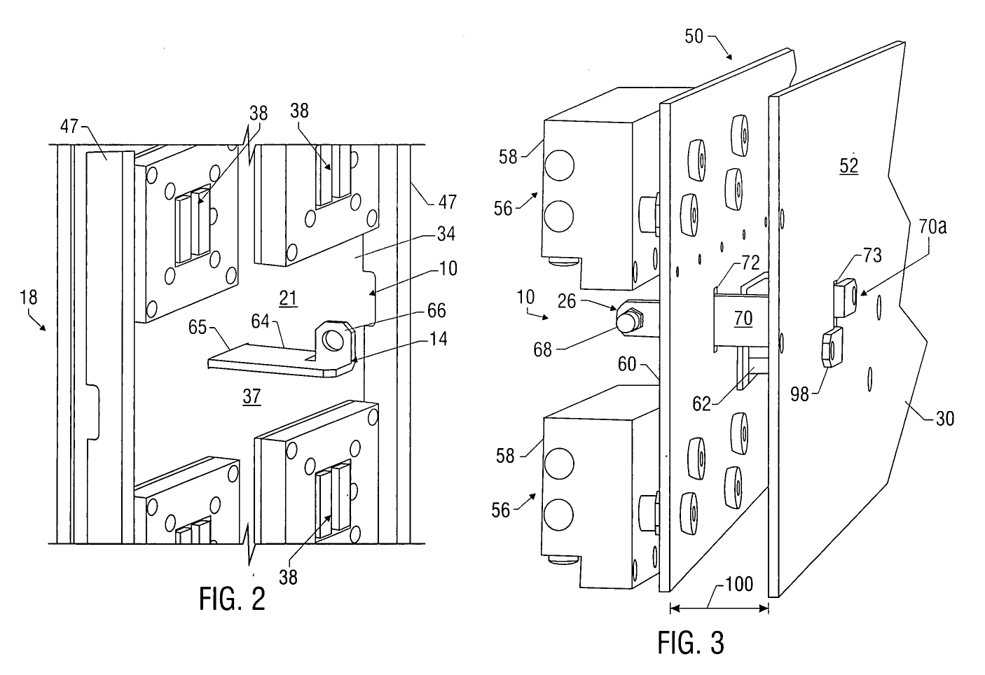

Referring now to the example of FIGS. 1 and 3, the base member 30 is rigidly fixed within the chamber 22 during operations, thought it may ultimately be removable if desired. In the illustrated embodiment, the base member 30 is a rear, or fixed, plate 52 of a thermal solution adapter (TSA) 50. The TSA 50 also includes at least one manipulator 56, which is movable relative to the rear plate 52 and engageable with the burn-in board 36 or devices (not shown) carried thereon. For example, the manipulators 56 may be multiple heat sinks 58 mounted on a retractable front plate 60 of the TSA 50 that is parallel to both the burn-in board 36 loaded in the chamber 22 and the rear plate 52. The manipulators 56 of this example align opposite the respective sockets (not shown) on the burn-in board 36 when the board 36 is fully loaded into the chamber 22.

In the example shown, the front plate 60 is laterally movable relative to the rear plate 52, such as by actuation of one or more force generating piston 62, such as a pneumatic cylinder or other mechanism. The front plate 60 opposes the front face 37 (FIG. 2) of the burn-in board 36 so that its forward movement causes engagement of the heat sinks 58 with the aligned sockets 38, or devices (not shown) held therein, on the burn-in board 36. The engagement of the heat sinks 58 with the burn-in board 36 (or devices carried thereon) may cause the application of compression to the board 36 and/or the rear plate 52, effectively pushing them away from one another. In this example, the compression forces extend from the rear plate 52 and force generating piston 62 through the heat sinks 58 to the burn-in board 36. It should be understood that the details, such as the construction, configuration and form, of the mobile member, base member, chamber and related components are not limiting upon the present invention.

Now in accordance with the present invention as used in the embodiment of FIG. 1, when the manipulators 56 engage the burn-in board 36 or devices carried thereon and apply forces to the burn-in board 36, the mated engager 14/receiver 26 combinations create tension, reducing deflection or bending of the board 36. In the particular embodiment shown, the desired coplanar or parallel relationship of the burn-in board 36 and the front and rear plates 60, 52 of the TSA 50 and the generally flat shape of the board 36 are maintained. Further with respect to this specific embodiment, substantial relative movement of the board 36 and rear plate 52 is prevented, preventing substantial horizontal loading of the card cage or rails (not shown). However, the present invention does not require each of these features or results in every embodiment or application.

The engagers 14 and receivers 26 may have any suitable form, construction, configuration, shape and location, as long as they serve as a temporary mechanical linkage between the mobile and base members 18, 30. In the embodiment of FIGS. 1-3, the engager 14 is a metal member 64 that extends through a slot 65 in the carrying board 34. The back end 64a of the member 64 is anchored to a horizontal stiffener 49 on the board 34, such as with screws. The front end 64b of the member 64 includes a loop portion 66 that is matable with a pin 68 extending from the receiver 26. The exemplary receiver 26 is a metal member 70 that extends through slots 72, 73 in the front and rear plates 60, 52, respectively. The back end 70a (FIG. 3) of the metal member 70 is anchored to the rear plate 52, such as with screws.

As shown in FIG. 1, when the burn-in board 36 of this embodiment is slid or inserted into the chamber 22, the loop portion 66 of the engager 14 fits over the pin 68 of the receiver 26. When the heat sinks 58 engage the board 36 or devices thereon and apply pressure, the pins 68 and loops 66 will engage, effectively reducing deflection or bowing of the board 36.

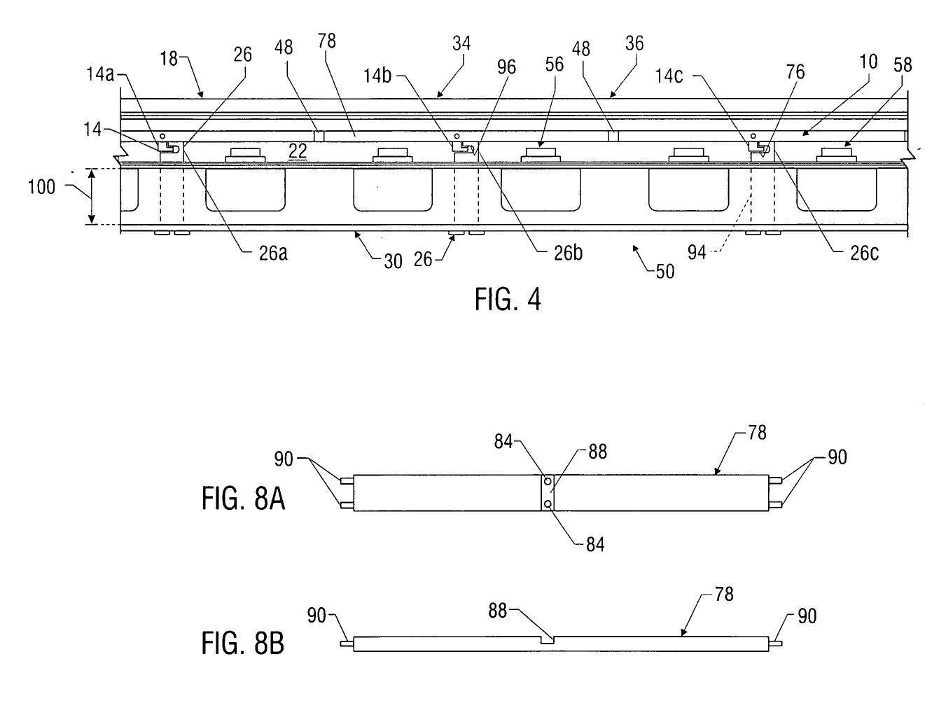

Now referring to the embodiment of FIG. 4, the DRA 10 includes first, second and third engagers 14a, 14b and 14c projecting from the mobile member 18 and mating with first, second and third receivers 26a, 26b, 26c that extend from the base member 30, respectively. The DRA 10 of this embodiment is configured to allow opposing tension and compression forces to counterbalance each other locally, generally preventing the forces to be applied to a long moment arm, thus reducing deflection of the mobile member 18.

In this example, the engagers 14a-c and receivers 26a-c are generally located across the center of the mobile member 1 8 and base member 30, respectively. Such configuration may be useful, for example, in applications where the mobile member 18 is supported in the chamber (not shown) at its top 18a, bottom 18b and side 18c, or a combination thereof, such as in a cage or on racks (not shown). In such instance, the most severe deflection of the mobile member 18 may be expected to occur at or near its middle, where the DRA 10 is therefore generally located.

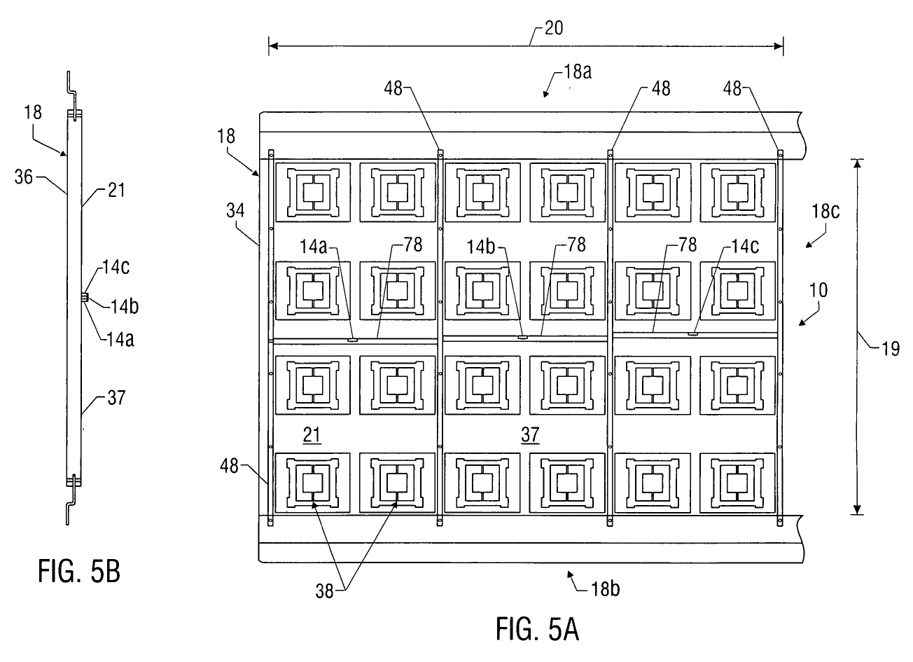

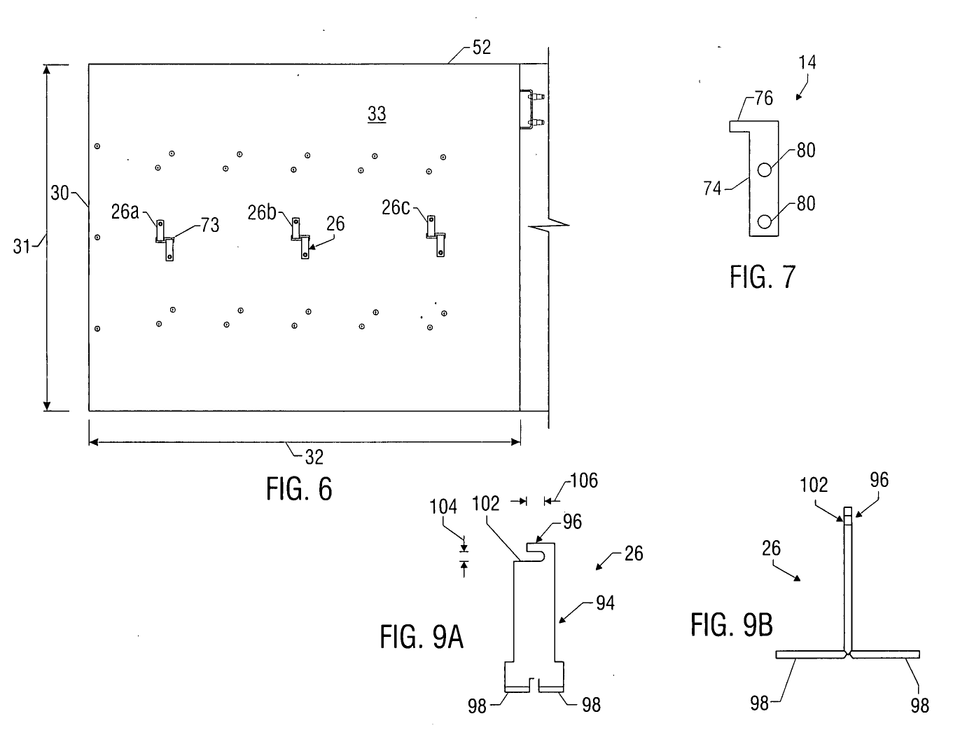

As shown in FIG. 5A, the illustrated engagers 14a-c are positioned proximate to the center of the height 19 of the mobile member 18 and in spaced relationship across the width 20 of the mobile member 18. Likewise, referring to FIG. 6, the exemplary receivers 26a-c are similarly positioned relative to the height 31 and width 32 of the base member 30. In the particular arrangement shown, the engagers 14a-c are slightly staggered along the height 19 of the mobile member 18 (see also FIG. 5B) and the receivers 26a-c are slightly staggered along the height 31 of the base member 30 to allow their intended paired mating when the mobile member 18 is inserted into the chamber (not shown) without interference by another of the engagers 14 or receivers 26. However, the present invention is not limited to the use of three engagers 14 and receivers 26 located in the configuration as shown. Any number of engagers 14 and receivers 26 may be used and positioned anywhere as desired.

Now referring to FIG. 7, each engager 14 of this embodiment includes a leg portion 74 and a foot portion 76. The leg and foot portions 74, 76 are sized so the engager 14 projects from the mobile member 18 sufficient to mate with and engage a receiver 26 (e.g. FIG. 4). The lee portion 74 is anchored to the mobile member 18 in any suitable manner. If desired, the leg portion 74 may be anchored to the mobile member 18 in a manner that assists in effectively transferring tension. For example, referring to FIG. 5A, the illustrated leg portion 74 anchors to an engager mount 78 connected between vertical stiffeners 48 on the front 21 of the mobile member 18, allowing forces to be distributed from the engagers 14 to the vertical stiffeners 48. Specifically with respect to the illustrated embodiment, referring to FIGS. 8A and 8B, one or more connectors (not shown), such as screws, is engaged between one or more threaded anchor holes 80 (FIG. 7) on the leg portion 74 and one or more holes 84 formed in a cutout portion 88 of the engager mount 78. The engager mount 78 also includes a pair of end connectors 90, such as dowel pins, at each of its ends for connection with the adjacent vertical stiffeners 48 (FIG. 5A).

Now referring to FIGS. 9A-B, each receiver 26 of this embodiment includes an elongated body 94, a hook-like potion 96 and a pair of fingers 98. The body 94 is sized to extend from the base member 30 sufficient to allow the hook-like portion 96 to mate with an engager 14 (e.g. FIG. 4). In the particular embodiment shown, the body 94 (FIG. 4) spans the gap 100 between the front and rear plates 60, 52 of the TSA 50.

The hook-like portion 96 of the illustrated receiver 26 is sized to mate with and engage the foot 76 of the corresponding engager 14. If desired, the hook-like portion 96 may have a mouth 102 that is oversized in width 104 and/or length 106 to allow proper mating and mechanical registration of the engager 14 and receiver 26 without interfering with the positioning of the mobile member 18 in the chamber 22. For example, the illustrated mouth 102 is shown in FIG. 4 slightly oversized in width 104 and length 106, providing spaces around the mating foot 76 of the engager 14.

The fingers 98 of the illustrated receiver 26 are anchored to the base member 30 in any suitable desired manner. If desired, the fingers 98 may be anchored to the base member 30 in a manner that assists in effectively transferring tension. For example, referring to FIG. 6, the fingers 98 are shown secured, such as with screws, to the back side 33 of the base member 30.

However, the above arrangements and component configurations are not limiting upon the present invention. Further, the above components may be constructed of any suitable materials and with any suitable dimensions.

Preferred embodiments of the present invention thus offer advantages over the prior art and are well adapted to carry out one or more of the objects of the invention. However, the present invention does not require each of the components and actions described above. Any one or more of the above components, features and processes may be employed in any suitable configuration without inclusion of other such components, features and processes. Further, the present invention is not limited to the above-described embodiments and methods of operation. Additional features, capabilities, components, functions, methods, uses and applications may be included.

The methods described above and any other methods which may fall within the scope of any of the appended claims can be performed in any desired suitable order and are not necessarily limited to the sequence described herein or as may be listed in any of the appended claims. Moreover, the methods of the present invention do not require use of the particular components or embodiments shown and described in the present specification, but are equally applicable with any other suitable structure, form and configuration of components.

Accordingly, while preferred embodiments of this invention have been shown and described, many variations, modifications and/or changes of the system, apparatus and methods of the present invention, such as in the components, details of construction and operation, arrangement of parts and/or methods of use, are possible, contemplated by the patentee, within the scope of the appended claims, and may be made and used by one of ordinary skill in the art without departing from the spirit or teachings of the invention and scope of appended claims. Thus, all matter herein set forth or shown in the accompanying drawings should be interpreted as illustrative and not limiting, and the scope of the invention and the appended claims is not limited to the embodiments described and shown herein.

1. An apparatus for reducing deflection of a mobile member in a chamber, the chamber including at least one base member and at least one retractable mechanism, the deflection of the mobile member caused by engagement of at least one retractable mechanism with the mobile member or at least one device carried thereon, the apparatus comprising:
at least three receivers projecting from a first side of the base member; and
at least three engagers projecting from a first side of the mobile member, the first sides of the base and mobile members facing each other, wherein each said engager is matable with one of said receivers when the mobile member is inserted into the chamber,
whereby when the at least one retractable mechanism engages the mobile member or at least one device carried thereon, each of said at least three engagers engages one of said at least three receivers, reducing deflection of the mobile member, and whereby each said engager is disengageable from one said receiver when the at least one retractable mechanism is disengaged from the mobile member or at least one device carried thereon and the mobile member is removed from the chamber.

2. The apparatus of claim 1 wherein the position of each said engager is staggered on the mobile member relative to adjacent said engagers and the position of each said receiver is staggered on the base member relative to adjacent said receivers, whereby the insertion and removal of the mobile member into and from the chamber is unimpeded by said at least three engagers and said at least three receivers.

3. The apparatus of claim 2 wherein said at least three engagers are disposed in spaced relationship proximate to the center of the mobile member and said at least three receivers are disposed in spaced relationship proximate to the center of the base member.

4. The apparatus of claim 3 wherein the mobile member includes a plurality of stiffeners, wherein each of said at least three engagers is interconnected with at least one of the stiffeners.

5. The apparatus of claim 4 further including a plurality of engager mounts, each said engager mount engaged with at least one of the stiffeners, wherein each of said at least three engagers is connected to at least one said engager mount.

6. The apparatus of claim 1 wherein the engagement of said at least three engagers and said at least three receivers provides tension to substantially counterbalance compression applied to the mobile member due to engagement of at least one retractable mechanism with the mobile member or at least one device carried thereon, wherein the compression is counterbalanced locally relative to said at least three engagers and said at least three receivers.

7. The apparatus of claim 6 further including at least one connector engageable between each said engager and the mobile member and at least one connector engageable between each said receiver and the base member, whereby the application of tension to said connectors is minimized by the connection of said at least three engagers with the mobile member and the connection of said at least three receivers with the base member.

8. The apparatus of claim 1 wherein the chamber is a burn-in chamber and the mobile member is a burn-in board.

9. The apparatus of claim 8 wherein the at least one retractable mechanism is a heat sink.

10. The apparatus of claim 9 wherein each said engager includes a loop and each said receiver includes a pin, wherein said loop of said engager is matable over said pin of said receiver.

11. The apparatus of claim 8 wherein each said engager includes a foot and each said receiver includes a hook-like portion, wherein said foot of said engager is matable with said hook-like portion of said receiver.

12. The apparatus of claim 1 wherein said at least three engagers are located on the mobile member proximate to the general area of greatest expected deflection of the mobile member.

13. An apparatus for reducing deflection of a carrying board in a chamber, the carrying board including at least two vertical stiffeners and being insertable into and removable from the chamber, the chamber including at least one thermal solution adapter having a fixed plate mounted within the chamber and a plurality of heat sinks, the heat sinks being movable relative to the fixed plate and into engagement with the carrying board or at least one device disposed upon the carrying board, the deflection of the carrying board being caused by engagement of at least one heat sink with the carrying board or at least one device carried thereon, the apparatus comprising:
at least one receiver projecting from a first side of the fixed plate proximate to the center of the height of the fixed plate; and
at least one engager projecting from a first side of the carrying board proximate to the center of the height of the carrying board, the first sides of the carrying board and fixed plate facing each other, said at least one engager being interconnected with at least one of the vertical stiffeners, each said at least one engager being matable with one of said at least one receiver when the carrying board is inserted into the chamber,
whereby when the at least one heat sink engages the carrying board or at least one device carried thereon, each of said at least one engager engages one of said at least one receiver, reducing deflection of the carrying board, and whereby each said at least one engager is disengageable from said at least one receiver after the at least one heat sink is disengaged from the carrying board or at least one device carried thereon and the carrying board is removed from the chamber.

14. The apparatus of claim 13 further including at least two said engagers and at least two said receivers, wherein the position of each said engager is staggered on the carrying board relative to any adjacent said engagers and the position of each said receiver is staggered on the fixed plate relative to adjacent said receivers.

15. The apparatus of claim 14 wherein said at least two engagers are disposed in spaced relationship proximate to the center of the carrying board and said at least two receivers are disposed in spaced relationship proximate to the center of the fixed plate.

16. The apparatus of claim 13 further including a plurality of engager mounts, each said engager mount engaged with at least one vertical stiffener, wherein each said engager is connected to at least one said engager mount.

17. The apparatus of claim 13 wherein the engagement of said at least one engager and said at least one receiver provides tension to substantially counterbalance compression applied to the carrying board due to engagement of at least one heat sink with the carrying board or at least one device carried thereon, wherein the compression is counterbalanced locally relative to said at least one engager.

18. The apparatus of claim 17 further including at least one connector engageable between each said engager and the carrying board and at least one connector engageable between each said receiver and the fixed plate, whereby the application of tension to said connectors is minimized by the connection of said at least one engager with the carrying board and the connection of said at least one receiver with the fixed plate.

19. The apparatus of claim 13 wherein the chamber is a burn-in chamber, the carrying board is a burn-in board and the at least one heat sink is mounted to a front plate that is movable relative to the fixed plate.

20. The apparatus of claim 19 wherein when the burn-in board is inserted in the chamber, the burn-in board is an at least substantially parallel to the fixed plate, wherein the engagement of said at least one engager with at least one said receiver assists in maintaining the parallel relationship of the burn-in board and the fixed plate.
